(19) United States
(12) Patent Application Publication
(10) Pub. No.: US 2019/0096573 A1
(43) Pub. Date: Mar. 28, 2019

(54) METHOD FOR FLUX RESTORATION FOR UNINTERRUPTIBLE POWER SUPPLY STARTUP

(71) Applicant: S&C Electric Company, Chicago, IL (US)

(72) Inventors: David Glenn Porter, East Troy, WI (US); William Yadusky, Franklin, WI (US)

(73) Assignee: S&C Electric Company, Chicago, IL (US)

(21) Appl. No.: 16/115,207

(22) Filed: Aug. 28, 2018

Related U.S. Application Data
(60) Provisional application No. 62/561,852, filed on Sep. 22, 2017.

(51) Int. Cl. H01F 27/42; G01R 33/00; G05F 1/32; H02J 9/06

(52) U.S. Cl. CPC H01F 27/422; G01R 33/0011; G01R 19/16547; H02J 9/062; G05F 1/32

(57) ABSTRACT

Apparatuses and methods are provided for restoring flux in a startup of an uninterruptible power supply device. The uninterruptible power supply device passes voltage to loads while offline. Upon occurrence of a utility disturbance, the output voltage is adjusted while maintaining RMS voltage within a pre-specified window in order to restore flux during startup of the uninterruptible power supply device.

### CROSS-REFERENCE TO RELATED APPLICATION

This application claims the benefit of priority from the U.S. Provisional Application No. 62/561,852, filed on Sep. 22, 2017, the disclosure of which is hereby expressly incorporated herein by reference for all purposes.

### TECHNICAL FIELD

The present disclosure relates to electric power distribution systems, and more particularly, to an apparatus and method for an offline uninterruptible power supply (UPS) at startup, or a microgrid switch in electric power distribution systems.

### BACKGROUND

Consumers rely on electrical equipment powered from utility-provided alternating-current (AC) power sources. However, commercial power reliability may not suffice for certain applications, for example, for computer facilities, government systems, or industrial motor loads. Therefore, an uninterruptible power supply (UPS) power source may be desirable to supplement or substitute for a utility-provided AC power source.

With the rapid advance of information technology and high-tech industries, most of the sophisticated electronic instruments and other devices rely on high-quality power supply to maintain normal operations. An uninterruptible power supply serves as a fail-safe power supply that can ensure the reliability of power supply and provide high-quality electricity. Thus far, uninterruptible power supply has become a solution for providing electricity with high-quality and high reliability.

Accordingly, it is desirable to provide high-quality electricity. It is also desirable to restore flux in downstream transformers at the startup of an offline uninterruptible power supply. Furthermore, other desirable features and characteristics of the present invention will become apparent from the subsequent detailed description of the invention and the appended claims, taken in conjunction with the accompanying drawings and this background of the invention.

### BRIEF DESCRIPTION OF THE DRAWINGS

The drawings described herein are for illustrative purposes only of selected embodiments and not all possible implementations, and are not intended to limit the scope of the present disclosure.

FIG. 1 is a flowchart showing operation for a UPS startup;

FIG. 2 is a flowchart showing operation at UPS startup with flux restoration;

FIG. 3 is a graph depicting the effect of a disturbance upon voltage and flux;

FIGS. 4-6 are flow charts depicting an operational scenario for addressing the loss of flux;

FIG. 7 is a graph depicting the effect of restoring flux at UPS startup; and

FIG. 8 is a functional block diagram of a UPS that is configured to restore flux at UPS startup.

Corresponding reference numerals indicate corresponding parts throughout the several views of the drawings.

### DETAILED DESCRIPTION

In accordance with the present disclosure, apparatuses, systems, and methods are provided for restoring transformer flux at the startup of an offline UPS. Also disclosed are apparatuses, systems, and methods for restoring the flux without incurring a high or low RMS voltage for UPS startup.

Example embodiments will now be described more fully with reference to the accompanying drawings. There is no intention to be limited by any principle presented in the following detailed description.

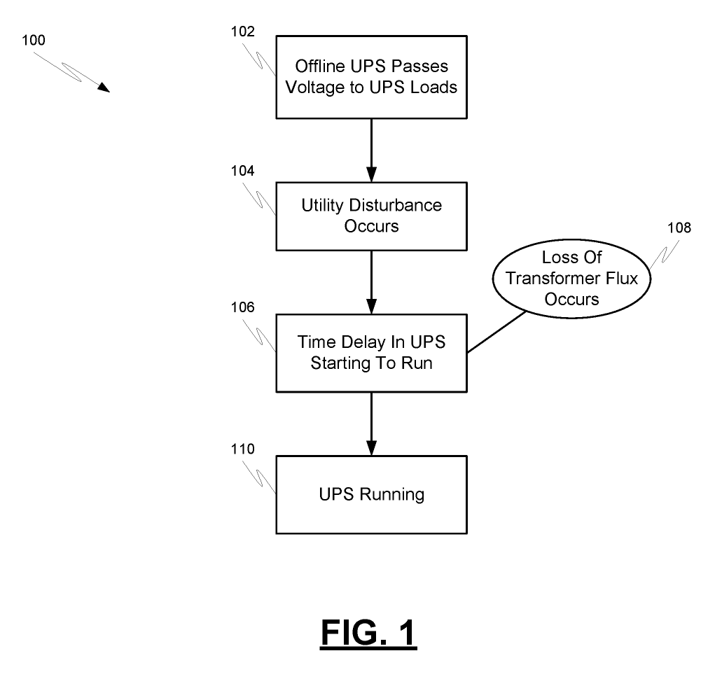

FIG. 1 depicts at 100 a process that utilizes an uninterruptible power supply within an electrical power distribution system. The uninterruptible power supply, in this example, is mounted between the external power source and the load. When the external power source, such as a commercially available AC power, is able to supply the power required by the load, the uninterruptible power supply can supply power synchronously to the load or convert the commercially available AC power into backup power so as to store the backup power in a rechargeable battery. In case that the commercially available AC power is interrupted or abnormal, the UPS can convert the backup power stored in the rechargeable battery into AC power and transmit the AC power to the load, thereby ensuring the normal operation of the load.

As indicated at 102, the UPS while offline passes the utility or generator voltage from the UPS input to the UPS loads. When a utility disturbance occurs as depicted at 104, a time delay occurs before the UPS begins to operate as indicated at 106. For example, the UPS takes time to detect the disturbance. Also, the UPS takes time to turn off the power electronic switch upon a disturbance. After the time delay, the UPS can start running as indicated at 110.

For the time the offline UPS is not running because of the detection and start up delays, the load is losing RMS (root mean square) voltage and any transformers downstream are losing flux as indicated at 108. The problem with the loss of flux is that when the UPS starts running, the flux in downstream transformers—the flux being proportional to the time-integral of the transformer voltage—is then no longer matched to the applied voltage. If the transformer voltage is abruptly restored to a normal voltage from an abnormal voltage, then the transformer flux will contain an offset which may result in saturation, large pulses of current, and deterioration of voltage quality as seen by the load.

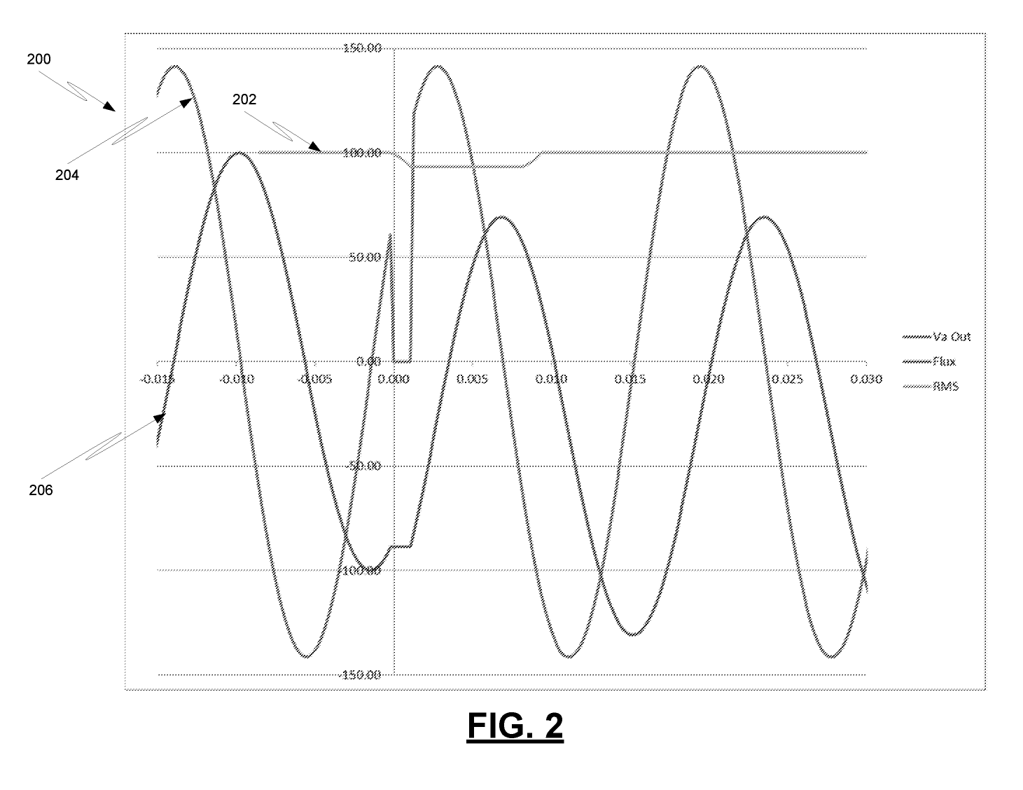

FIG. 2 illustrates the flux problem associated with a UPS startup. Graph 200 of FIG. 2 shows a disturbance due to the detection and start up delays. The voltage before and after the time delays is the utility voltage. The voltage after the time delay is the ideal UPS output voltage.

FIG. 2 shows the RMS voltage 202, the simulated output voltage 204 where the UPS sees the disturbance then runs, and the downstream transformer flux at 206. As shown in the graph 200, the offset in transformer flux due to the voltage disturbance is 30% (giving a peak flux of 130%) is sufficient to saturate downstream transformers causing voltage distortion as a result of the high flux.

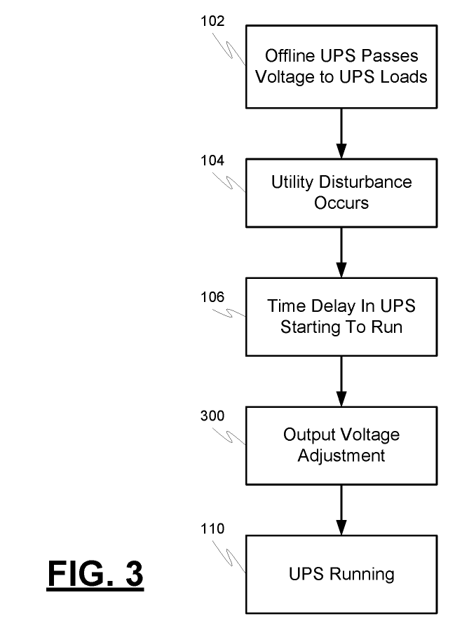

FIG. 3 depicts a method at 300 to restore flux for UPS startup. In FIG. 3, the method at 300 adjusts the output voltage to bring the flux back in line. For example, if the flux is lower than desired as in FIG. 2, the positive half voltage can be increased and the negative half voltage can be decreased. The adjustment is done in consideration of the situation that if the voltage is too high or too low, the RMS voltage will prolong the disturbance seen by the load. The method 300 restores the flux without incurring a high or low RMS. For example, the positive half voltage is increased to 108% if the flux needs to move more positive, and decreased to 92% on the negative half voltage to also move the flux in the positive direction. This keeps the RMS voltage within ±10% while the flux is being corrected.

The method 300 performs the flux restoration method for a short time after the UPS starts running, that is until the flux is back to where it should be. The time can be one cycle or less (e.g., 16.67 ms at 60 Hz). At the start of the run, a correction is applied to the voltage to accomplish flux correction with the goal of not saturating the output transformer. This correction moves the actual flux toward the ideal flux by using a higher or lower AC output voltage. When the flux is within 2% of the ideal flux, the method 300 ramps back the correction until it is running at the nominal voltage.

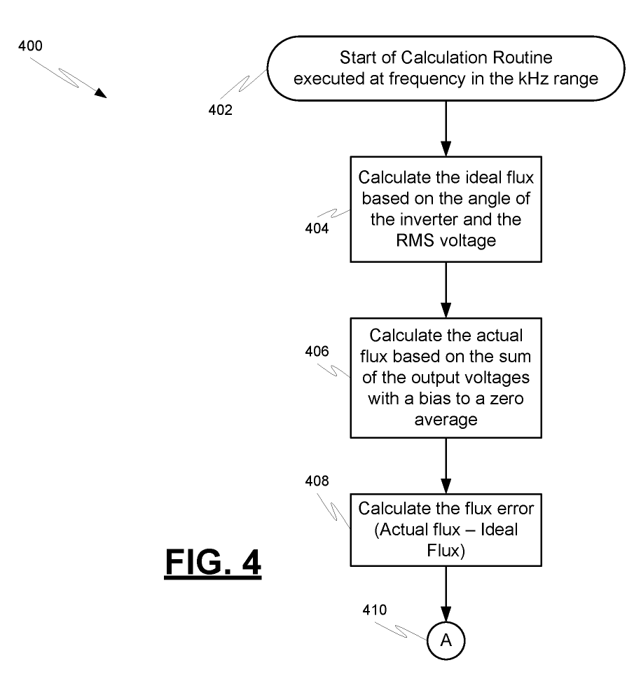

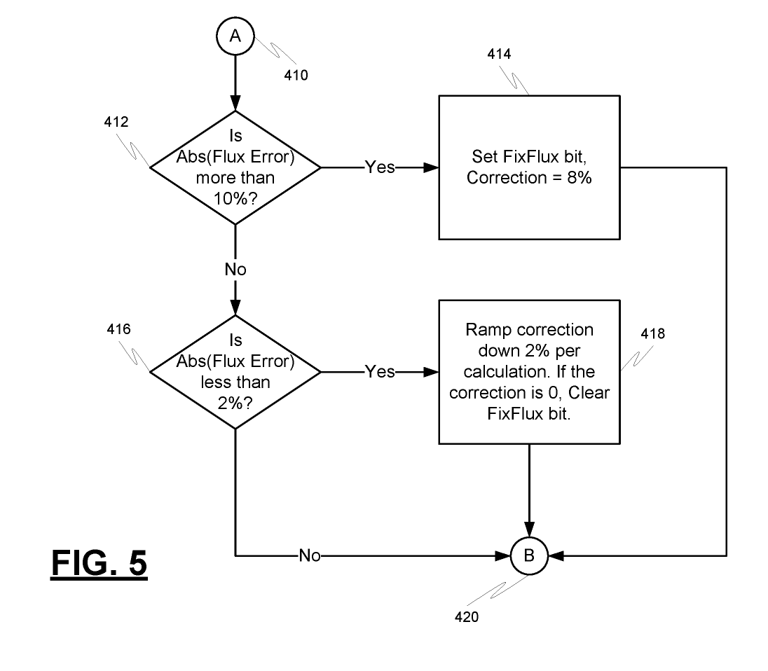

FIGS. 4-6 depicts an additional embodiment of a method 400 for flux restoration in a situation involving UPS startups. The method 400 starts at 402 and is executed at a frequency in the kHz range. Process block 404 calculates the ideal flux based on the electrical angle of the inverter and the RMS voltage. Process block 406 calculates the actual flux based on the sum of the output voltages with a bias to a zero average. Process block 408 calculates the flux error by finding the difference between the actual flux and the ideal flux. Processing continues on FIG. 5 as indicated by continuation marker 410.

FIG. 5 indicates that decision block 412 examines whether the absolute value of the flux error is above a pre-specified threshold (e.g., 10%). If it is, then the bit FixFlux is set to indicate whether the flux restoration method should be used. Also, the correction value is set, in this example, to 8% for when the UPS starts running.

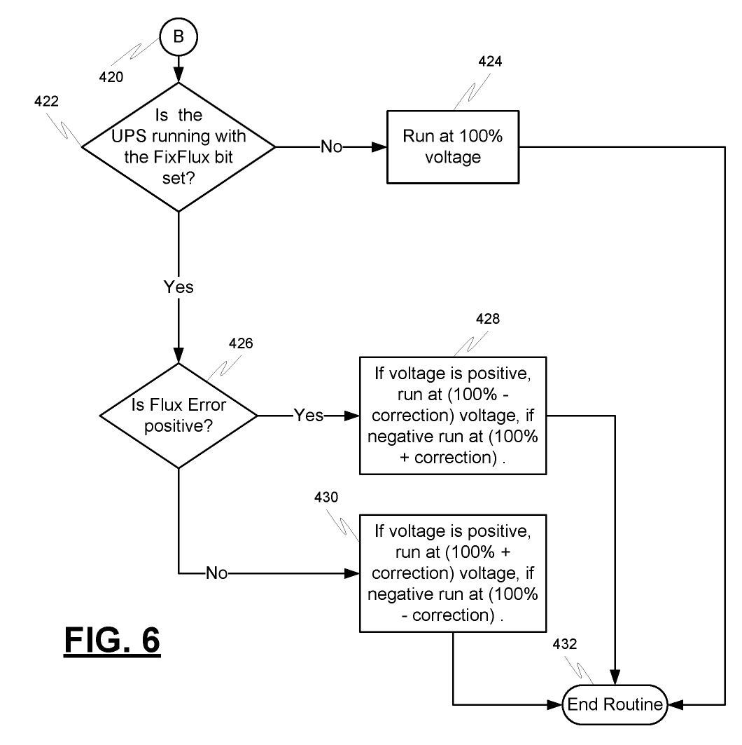

If decision block 412 determines that the absolute value of the flux error is not more than the pre-specified threshold, then decision block 416 examines whether the absolute value of the flux error satisfies other pre-specified criteria. In this example, the single criterion is whether the absolute value of the flux error is less than 2%. If it is, then a ramp correction down 2% is made for each calculation. If the correction after an iteration of the method 400 is zero, then the FixFlux bit is cleared. However, if the absolute value of the flux error is not less than 2%, then processing continues on FIG. 6 as indicated by continuation marker 420.

FIG. 6 indicates that decision block 422 examines whether the UPS is running with the FixFlux bit set. If it is not, then the UPS is operated at 100% voltage as indicated at 424, and the method terminates at 432. If the UPS is running with the FixFlux bit set, then decision block 426 examines whether the flux error value itself is positive. If the flux error is positive, then the UPS is run at “100%−correction” voltage if the UPS voltage is also positive as indicated at process block 428. If the UPS voltage is negative, then the UPS is run at “100%+correction” voltage. The method 400 then terminates as indicated at 432.

If decision block 426 determines that the flux error value is not positive, then the UPS is run at “100%+correction” voltage if the UPS voltage is positive as indicated at process block 430. If the UPS voltage is negative, then the UPS is run at “100%−correction” voltage. The method 400 then terminates as indicated at 432.

Benefits of the method 400 include the reduction in downstream transformer peak flux. If the peak flux gets too high, the transformer will saturate. A saturated transformer will not provide the desired voltage. This can cause the disturbance to be extended beyond where it would be with the method 400. Another benefit is that the method 400 can be used in many different types of applications, such as to enhance the response of any off-line UPS, enhance the response of an islanding inverter system that has an output that is connected to a source that has disturbances such as a utility or generator, etc. To perform the calculations of the method 400, a device can be used that can perform digital calculations, such as a controller with a microprocessor, digital signal processor (DSP), microcontroller, or field programmable gate array (FPGA), etc.

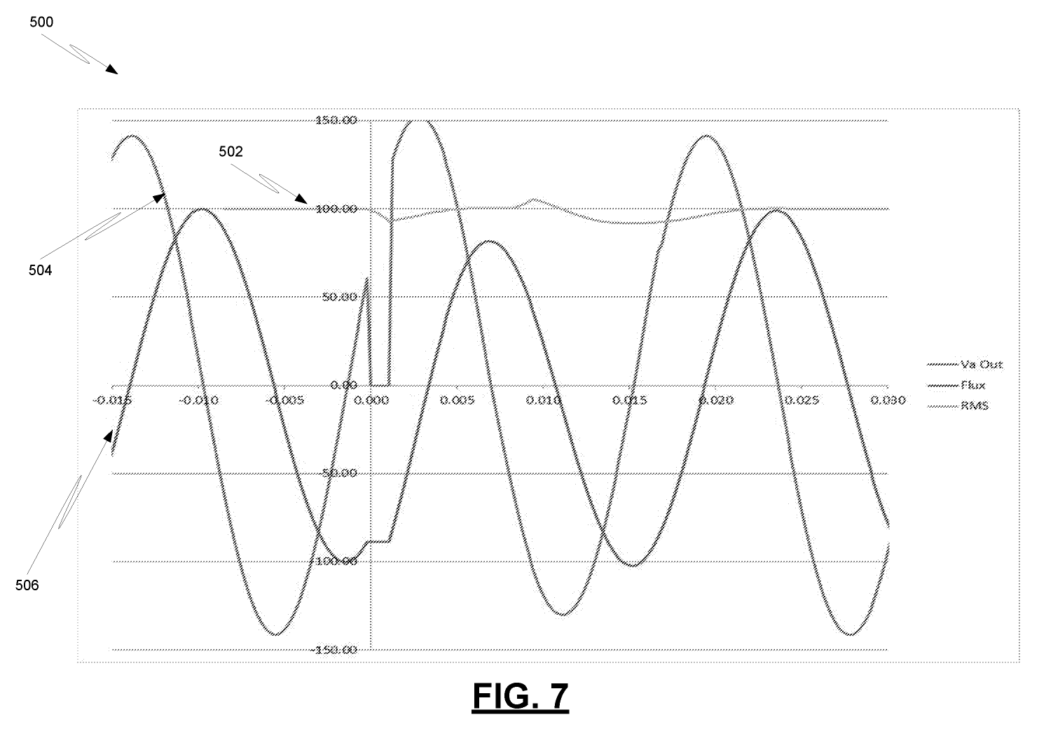

FIG. 7 shows at 500 the effect of the method 400 where the positive half voltage was increased to 108% if the flux needs to move more positive, and decreased to 92% on the negative half voltage to also move the flux in the positive direction. FIG. 7 shows the effect of this change in output voltage 504.

With reference to the output voltage 504 on FIG. 7, the first positive half cycle after the disturbance is higher than the positive half cycle before the disturbance, and the negative half cycle is lower than the negative half cycle before the disturbance. This change brings the flux 506 back to center more quickly, and the worst case flux in now 2.2% higher than it was in the pre-disturbance waveform which provides a peak flux that is 102.2% of the pre-disturbance flux. This reduction can keep the transformer from saturating.

The cost of this correction is the change in RMS voltage 502. In FIG. 2, the RMS voltage 202 goes down to a fixed level, then returns a half cycle later. In FIG. 7, the RMS voltage 502 goes down, but then up as the AC voltage is run at 108%. Then when the voltage goes negative, the RMS voltage 502 again comes down because it is running at 92% voltage. Finally, after about 22 ms, the RMS voltage 502 stabilizes at 100%.

Tables 1 and 2 below illustrate what may happen at different angles and different sag levels (where voltage sags are reduction in RMS voltage levels). Table 1 shows the un-corrected data for a sag to 0% voltage at angles from 0 to 165° in the first three columns after the angle. This shows that if a combination of a 10% change in RMS voltage and 10% loss of flux is used to detect a disturbance due to a voltage sag, the minimum voltage ranges from 96% to 86.9% voltage if no correction is used. The flux goes up to between 126.5% and 138.9%. When corrections of ±8% to the voltage are applied, the worst case flux is limited to 117.3%. FIGS. 2 and 7 are for the 30° case in Table 1 below:

| | Sag to 0% | | | | | |
|---|---|---|---|---|---|---|
| | No Correction | | | +/−8% correction | | |
| Angle in | Min | Max | Max | Min | Max | Min |
| degrees | RMS | RMS | Flux | RMS | RMS | Flux |
| 0 | 96.0% | 100.0% | 126.5% | 93.7% | 106.8% | 100.7% |
| 15 | 95.7% | 100.0% | 126.0% | 93.9% | 106.7% | 100.7% |
| 30 | 93.2% | 100.0% | 130.9% | 92.0% | 105.7% | 102.2% |
| 45 | 91.5% | 100.0% | 131.6% | 91.5% | 104.4% | 104.2% |
| 60 | 88.6% | 100.0% | 136.5% | 88.6% | 102.0% | 111.1% |
| 75 | 86.9% | 100.0% | 138.9% | 86.9% | 103.3% | 115.6% |
| 90 | 87.1% | 100.0% | 138.5% | 85.6% | 104.7% | 117.3% |
| 105 | 89.1% | 100.0% | 135.7% | 84.9% | 105.6% | 116.3% |
| 120 | 92.2% | 100.0% | 130.9% | 86.0% | 106.3% | 112.5% |
| 135 | 95.5% | 100.0% | 122.9% | 88.2% | 102.3% | 106.2% |
| 150 | 98.2% | 100.0% | 115.0% | 90.7% | 100.0% | 101.0% |
| 165 | 94.8% | 100.0% | 125.8% | 94.1% | 106.6% | 100.8% |

Table 2 below shows the same data as Table 1, but uses a sag to 50% instead of a sag to 0%. This is more typical of a utility disturbance upstream and on a different feeder than when the UPS is on. The worst case after correction is 102.6% flux in the downstream transformers.

| | Sag to 50% | | | | | |
|---|---|---|---|---|---|---|
| | No Correction | | | +/−8% correction | | |
| Angle in | Min | Max | Min | Min | Max | Max |
| degrees | RMS | RMS | Flux | RMS | RMS | Flux |
| 0 | 94.9% | 100.0% | 119.0% | 94.6% | 106.0% | 100.8% |
| 15 | 94.6% | 100.0% | 118.9% | 94.6% | 105.9% | 100.7% |
| 30 | 92.0% | 100.0% | 122.2% | 92.0% | 104.6% | 100.7% |
| 45 | 90.1% | 100.0% | 123.1% | 90.1% | 103.0% | 100.5% |
| 60 | 89.5% | 100.0% | 122.2% | 89.5% | 101.2% | 100.8% |
| 75 | 89.3% | 100.0% | 123.4% | 88.3% | 100.0% | 100.9% |
| 90 | 88.7% | 100.0% | 122.9% | 86.9% | 100.3% | 102.2% |
| 105 | 90.6% | 100.0% | 121.0% | 86.2% | 100.3% | 102.1% |
| 120 | 92.2% | 100.0% | 119.8% | 86.4% | 100.4% | 102.6% |
| 135 | 96.1% | 100.0% | 115.1% | 88.7% | 100.0% | 100.7% |
| 150 | 88.4% | 100.0% | 122.6% | 88.4% | 104.1% | 100.1% |
| 165 | 93.8% | 100.0% | 119.0% | 93.8% | 105.7% | 100.5% |

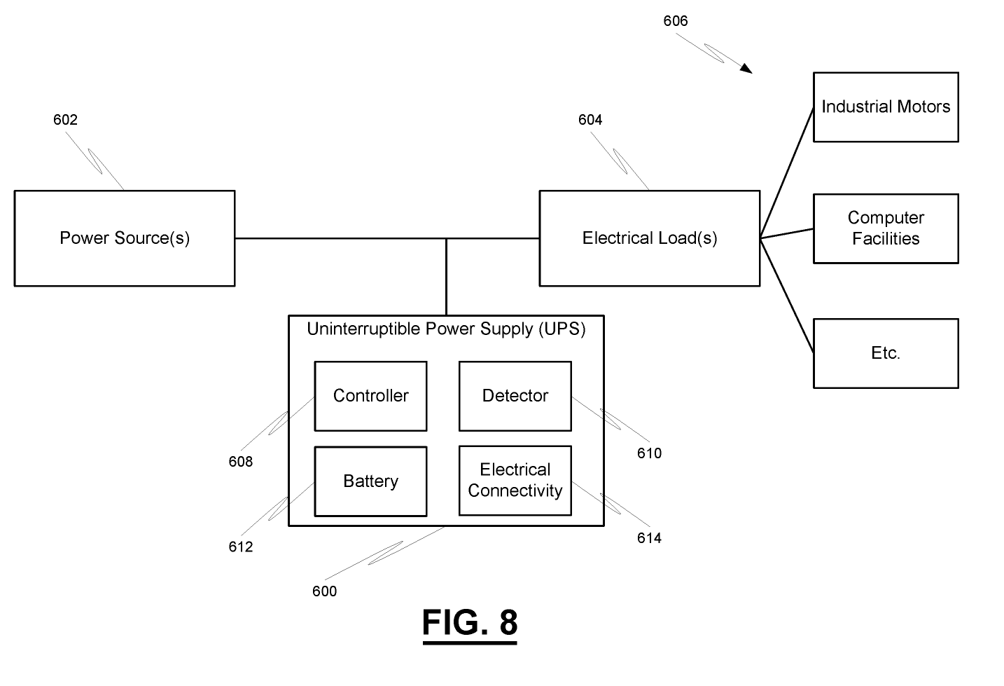

FIG. 8 is a functional block diagram of an uninterruptible power supply device (UPS) 600 in accordance with an embodiment. The uninterruptible power supply device 600 passes power from one or more power sources 602 to at least one electrical load 602. An electrical load 602 could include one or more of the loads shown at 606 (e.g., industrial motors, computer facilities, etc.). The uninterruptible power supply device 600 may include many different types of components, such as a controller 608, detector 610 for detecting occurrence of a utility disturbance, and battery 612.

More specifically, electrical connectivity 614 passes voltage to the electrical load(s) 604 with the uninterruptible power supply device 600 being offline. Upon detection of a utility disturbance by the detector 610, the controller 608 determines adjustment values of output voltages for restoring flux during startup of the uninterruptible power supply device 600. The adjusting of the output voltage ceases after the flux is restored to a pre-specified level. It should be understood that different configurations can be used. For example, controller 608 can be used irrespective of the battery 612 or other storage media that provides the flux restoration functionality.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure. As an example of the wide variations, embodiments may be configured as follows. The method can be varied to use different correction waveforms than sine waves. The goal of these waveforms is to restore flux as quickly as possible. A secondary goal may be to minimize the impact to RMS content. Correcting the flux quickly can be most effectively done with a flat top voltage. This can result, however, in high RMS voltages if taken to extremes.

Two waveforms have been presented, using sine waves of varying magnitudes, and using flat top waveforms. The goal of these waveforms is to get the transformer flux to be correct with a secondary goal of keeping the RMS voltage within limits, typically 100±10%.

1. A method for restoring flux for startup of an uninterruptible power supply device, comprising:
passing voltage to loads with the uninterruptible power supply device being offline;
detecting occurrence of a utility disturbance; and
adjusting output voltage for restoring flux during startup of the uninterruptible power supply device while maintaining RMS voltage within a pre-specified window;
wherein the adjusting of the output voltage ceases after the flux is restored to a pre-specified level.

2. The method of claim 1 further comprising:
determining that the flux is lower than the pre-specified level; and
increasing or decreasing the positive half voltage and increasing or decreasing negative half voltage in order to bring the transformer flux back to where the transformer has no offset.

3. The method of claim 1, wherein time of the adjusting of the output voltage is one cycle or less than one cycle.

4. The method of claim 1, wherein the adjusting of the output voltage is performed by using a pre-determined correction amount.

5. The method of claim 4, wherein the correction amount is set to prevent saturating an output transformer while maintaining the RMS voltage within the specified window.

6. The method of claim 1 further comprising:
calculating an ideal flux value based on electrical angle of an inverter and RMS voltage;
calculating an actual flux value based on the sum of the instantaneous output voltages;
calculating a flux error by determining difference between the actual flux value and the ideal flux value; and
using the calculated flux error in the adjusting of the output voltage.

7. The method of claim 1,
calculating an ideal flux value based on electrical angle of an inverter and RMS voltage;
calculating an actual flux value based on the sum of the instantaneous output voltages;
calculating a flux error by determining difference between the actual flux value and the ideal flux value;
using a ramp correction down value based upon determining whether an absolute value of the flux error satisfies pre-specified criteria.

8. The method of claim 1, wherein the adjusting of the output voltage is used for enhancing response of the off-line UPS.

9. The method of claim 1, wherein the adjusting of the output voltage is used for enhancing response of an islanding inverter system that has an output that is connected to a source that has disturbances.

10. The method of claim 1, wherein correction waveforms other than sine waveforms are used for the uninterruptible power supply device.

11. An uninterruptible power supply device that restores flux during startup, comprising:
electrical connectivity for passing voltage to loads with the uninterruptible power supply device being offline;
a detector for detecting occurrence of a utility disturbance; and
a controller for determining adjustment values of output voltages for restoring flux during startup of the uninterruptible power supply device while maintaining RMS voltage within a window;
wherein the adjusting of the output voltage ceases after the flux is restored to a pre-specified level.

12. The device of claim 11 wherein the controller determines that the flux is lower than the pre-specified level;
wherein positive half voltage is increased or decreased, and negative half voltage is increased or decreased in order to eliminate the offset in the flux of a downstream transformer by adjusting the output voltage.

13. The device of claim 11, wherein time of adjusting the output voltage is one cycle or less than one cycle.

14. The device of claim 11, wherein adjusting the output voltage is performed by using a pre-determined correction amount.

15. The device of claim 14, wherein the correction amount is set to prevent saturating an output transformer while maintaining the output RMS voltage within the pre-specified window.

16. The device of claim 11, wherein the controller is configured to:
calculate an ideal flux value based on electrical angle of an inverter and RMS voltage;
calculate an actual flux value based on the sum of the instantaneous output voltages;
calculate a flux error by determining difference between the actual flux value and the ideal flux value; and
use the calculated flux error in the adjusting of the output voltage.

17. The device of claim 11, wherein the controller is configured to:
calculate an ideal flux value based on electrical angle of an inverter and RMS voltage;
calculate an actual flux value based on the sum of the instantaneous output voltages;
calculate a flux error by determining difference between the actual flux value and the ideal flux value;
use a ramp correction down value based upon determining whether an absolute value of the flux error satisfies pre-specified criteria.

18. The device of claim 11, wherein adjusting the output voltage is used for enhancing response of the off-line UPS.

19. The device of claim 11, wherein adjusting the output voltage is used for enhancing response of an islanding inverter device that has an output that is connected to a source that has disturbances.

20. The device of claim 11, wherein correction waveforms other than sine waveforms are used for the uninterruptible power supply device.
